(19) United States
(12) Patent Application Publication
(10) Pub. No.: US 2015/0068587 A1
(43) Pub. Date: Mar. 12, 2015

(54) Solar Power Panels, Arrays and Connection Systems

(71) Applicant: Sandia Solar Technologies LLC, Pagosa Springs, CO (US)

(72) Inventor: Henry L. Lomasney, Pagosa Springs, CO (US)

(73) Assignee: Sandia Solar Technologies LLC, Pagosa Springs, CO (US)

(21) Appl. No.: 14/218,840

(22) Filed: Mar. 18, 2014

Related U.S. Application Data
(60) Provisional application No. 61/801,772, filed on Mar. 15, 2013.

(51) Int. Cl. H01L 31/048; H02S 40/32; H02S 40/36

(52) U.S. Cl. CPC H01L 31/048; H02S 40/36; H02S 40/32
USPC 136/251

(57) ABSTRACT

An integrated and enclosed solar photovoltaic power producing panels and method of producing alternating current electrical power that combines and integrates all electrical and electronic elements within a non-metallic and dual-insulated enclosure arrangement within which the DC output of each of these solar modules is converted to AC. The AC may be distributed within the dual insulated enclosure and subsequently between panels in an array. The panels may be comprised of a unitary non-metallic insulating housing that extends the length and width of the panel. This housing may enclose the DC circuitry, the inverter, a suitable alternating bus array for transferring the AC power within the module and contact means for interconnecting the AC output between multiple modules. Each of the AC interconnect components can optionally be connected into an array, whereby the output is coupled, and ultimately delivered to a terminal junction box. This AC interconnect component is configured such that it sustains the dual insulation feature. This dual insulated power producing apparatus can optionally be configured with a framing system that is easily installed and can be directly mounted to a roof surface with non-metallic brackets and railing structures that further contributes to the safety features of the installation, by providing a system that is electrically insulated, less prone to a lightning strike or to a fire hazard in the case of contact by a downed power line.

### CROSS-REFERENCE TO RELATED APPLICATIONS

This application claims the benefit of U.S. Provisional Patent Application No. 61/801,772, filed Mar. 15, 2013, which application is incorporated herein by reference in its entirety.

### FIELD

This disclosure relates to photovoltaic devices and systems.

### SUMMARY

Embodiments described herein provide self-contained, alternating current (AC) photovoltaic (PV) power block devices that can facilitate a simplified installation, with embodiments being capable of installation in a “plug and play” fashion. Embodiments of the devices and systems disclosed herein employ a “dual insulation” design. Embodiments of the devices and systems disclosed herein employ a dual insulation design. In this context, dual insulated may mean both a double insulated electrical device and a dual insulated assembly as is typically used for dual insulated pipe, wire, clothing and many other things. This system also permits substantial reduction or elimination of external wiring that may be typically found in PV devices. Embodiments disclosed herein also can include a polarized alignment feature that reduces or substantially eliminates the possibility of an installation error. Embodiments described herein also can include few or substantially no external metal parts associated with the module, thereby potentially improving safety and reducing or eliminating the need for grounding circuits and the potential hazards associated with grounding faults. Embodiments described herein also can reduce or substantially eliminate the hazard of lighting strikes that are can be associated with roof-mounted and ground-mounted solar arrays. Embodiments of the devices and systems disclosed herein also include the positioning of an AC-PV system within an enclosure that provides a hermetic (i.e., airtight), substantially airtight, waterproof or substantially waterproof seal for the electrical components and their electrical interconnection media. The enclosure may be polymeric in nature.

Embodiments disclosed herein thus provide a PV device with one or more of the following features:
a dual insulation feature;
a dual insulation feature that can be achieved within an integrated system by means of an enclosure;
a dual insulation feature that can be achieved within an integrated system by means of a polymeric enclosure;
use of conventional wiring insulation within the internal electrical and electronic system; and
use of polymeric materials, e.g., potting compounds, and the use of embedded electrical connectors that are configured so as to provide reliable electrical distribution within a dual insulation package.

Embodiments of a dual insulated AC-PV power block provide an integral and electrically isolated system that can comprise: (i) the structure of the solar module, including its absorber cell network, (ii) the photovoltaic electrical (DC) system, (iii) the electronic system that converts the DC into AC, and (iv) the electrical transmission network that communicates the AC output to the desired destination. In embodiments of such AC-PV devices described herein, external wiring may be reduced or substantially eliminated. Such embodiments may facilitate quality assurance testing by permitting the fully integrated system to be tested prior to factory release. Such embodiments also may be more easily installed due to modularity that permits multiple devices to be readily connected or “plugged in,” which optionally may be further facilitated by a connection system that also may be integral to the devices. Embodiments of such an integral connection system include a pultrusion framing system as disclosed herein.

Embodiments of the devices and systems disclosed herein can be installed wherever solar devices may be installed, e.g., on a roof or in ground mount array. Embodiments of brackets disclosed herein may assist in such installation.

### DEFINITIONS

The following definitions are used in this disclosure:

“Dual insulated” as used herein means double insulated. For example, in embodiments described herein, such dual insulation is achieved by the use of a glass fiber reinforced power rail enclosure, as well as the dielectric module enclosure and the embedment of electronics within a reactive polymer potting medium.

“String” means a set of AC modules connected in parallel to a dedicated branch circuit

“Array” means an installation of one or more strings connected to the structure's AC service equipment.

“Grounding circuit” means a ground bond circuit that positively maintains safe voltages on the chassis of an electrical device. A grounding circuit helps prevent an electric shock resulting from an insulation failure. Grounding circuits can be tested to determine that the ground bond circuit positively maintains safe voltages on the chassis under test, even when exposed to a high current before a line protection circuit breaker device trips.

“Pultrusion” means a GFRP (Glass Fiber Reinforced Polymer) structure that has been produced, e.g., using a process that involves extruding a component fiber and polymer mixture thru a forming die, using a batch, continuous or semi-continuous process.

“3D-GFRP” means a three-dimension Glass Fiber Reinforced Polymer, which optionally can be used as an integral part of the power block. In embodiments, it can provides a structural feature to the solar module, and optionally can be integrated structurally with a pultruded power rail

“High Voltage Testing” means application of a significantly higher operating voltage than would normally be encountered under normal operating conditions.

“Insulation Resistance Testing” measures the total resistance of a product's insulation. This can optionally application of a 500V to 1000 V voltage. Normally the minimum acceptable resistance is 2 megaohms.

“Leakage Current Test” measures current leakage to check for undesireable current leakage.

“Photovoltaic Module” as used herein, means one or more solar cells contained in any type of enclosure, e.g., that which is generally referred to as a photovoltaic module.

### BRIEF DESCRIPTION OF THE FIGURES

The appended figures, briefly summarized below, are provided for exemplary understanding of this disclosure and do not limit this disclosure in any way. The dimensions provided in the figures are merely for illustration purposes and other dimensions may be used as desired and as appropriate.

FIGS. 1A and 1B illustrate an embodiment of a dual insulated 3D-GFRP AC-PV power rail and its associated installation bracket in accordance with this disclosure.

FIG. 2 illustrates an embodiment of a micro-inverter package embedded in a dual insulated 3D-GFRP AC-PV power rail in accordance with this disclosure.

FIG. 3 illustrates an embodiment of a module array assembly sequence that may be used with a dual insulated 3D-GFRP power block as disclosed herein.

FIG. 4 illustrates an embodiment of a plug-in electrical connector and its interface that may be used with the dual-insulated 3D-GFRP power rail as disclosed herein.

FIG. 5 illustrates an embodiment of a plug-in electrical connector and its interface that may be used with the dual-insulated 3D-GFRP as disclosed herein.

FIG. 6 illustrates an embodiment for attaching a dual insulated 3D-GFRP AC-PV in accordance with this disclosure to a grid interfacing junction/transition box.

FIG. 7 illustrates an embodiment for attaching a dual insulated 3D-GFRP AC-PV in accordance with this disclosure to a flat roof.

FIG. 8 illustrates an embodiment for incorporating a dual insulated 3D-GFRP AC-PV in accordance with this disclosure to a ground mounted array.

FIG. 9 illustrates an embodiment of an electrical interconnect system that may be used with a vertical power rail interconnection system in accordance with this disclosure for attaching a dual insulated 3D-GFRP AC-PV in accordance with this disclosure to a flat roof installation.

### DETAILED DISCUSSION

Today's PV power systems utilize a single PV module or multiple modules that are connected by combinations of series and parallel circuits. In the case of a single module system, the PV module is connected to the inverter or load through a junction box that incorporates fuse protection. These electrical components are external to the module enclosure. Such connections are typically provided beneath the module by plugging connectors together or with connections at distributed junction boxes.

An electrical system arrangement that is used with a conventional solar PV typically involves a solar photovoltaic DC power output circuit that feeds through a DC disconnect via an exposed wire circuit where it meets an inverter feature. This arrangement converts the DC electrical power into AC. The power may then be fed to a surge protection feature and then ultimately to a dedicated branch circuit within a service panel. This is a common way in which power from a solar absorber system that is generating DC power is converted to AC power, and subsequently for supplying this AC power to a microgrid array and ultimately to a utility grid network.

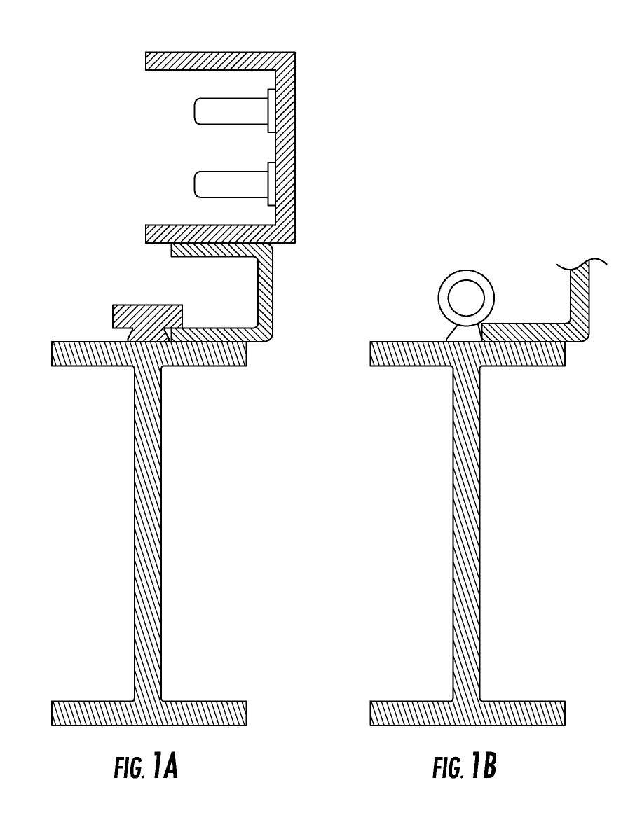

Referring now to the figures, FIGS. 1A and 1B, illustrate two possible embodiments of a dual insulated 3D-GFRP AC-PV power rail and its associated installation bracket for embodiments of the PV panels disclosed herein. FIG. 1A employs a welded attachment tab, whereas FIG. 1B employs aluminum tubing (shown as 9/16″ diameter).

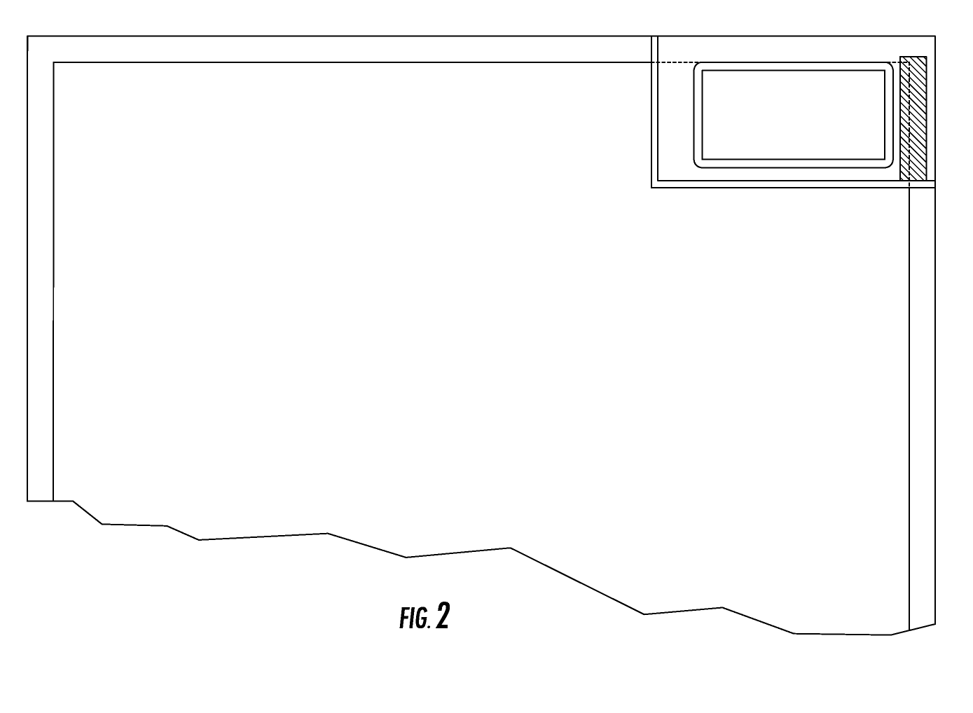

FIG. 2 provides a simplified schematic illustrating an embodiment of a plug-in electrical connector and its interface that may be used with the dual-insulated 3D-GFRP power rail as disclosed herein. This figure illustrates that the electronic micro-inverter may be incorporated as a integral part of an overall integral system. Here, the micro-inverter is embedded into the structural frame system in a manner that uses a potting feature such that it qualifies as a double insulated system. There is no externally exposed wiring in this embodiment. A structural frame is an integral part of the system; within which an electrically conductive bus bar system is embedded. In this embodiment, the structural system may be non-metallic, e.g., comprised of a glass fiber reinforced polymeric composite, optionally having a 3-dimensional design feature.

The design of the AC bus bar “halo,” which is illustrated in FIG. 2 and other figures of this disclosure, provides a mechanism to incorporate the AC distribution system as an integral part of the structural railing that frames the solar module. This AC bus bar halo thus enables the design of embodiments in which multiple panels are connected along their edges to form an array. In this embodiment, the bus bar structure consists of two separate bus-bar features: one is positive and one negative. They are configured such that they are located on the perimeter of the panel. They can be configured to be in a “halo” geometry or configuration around the periphery of the panel. This embodiment, which incorporates the AC bus bar around the periphery of the panel is referred to herein as a PV power block panel. As will be discussed in more detail below and in subsequent figures, this bus bar “halo” provides a facile mechanism for electrically connecting multiple panels in an array of these PV power block panels together. This electrical interconnect can take place along any of the panel's four structural frame faces.

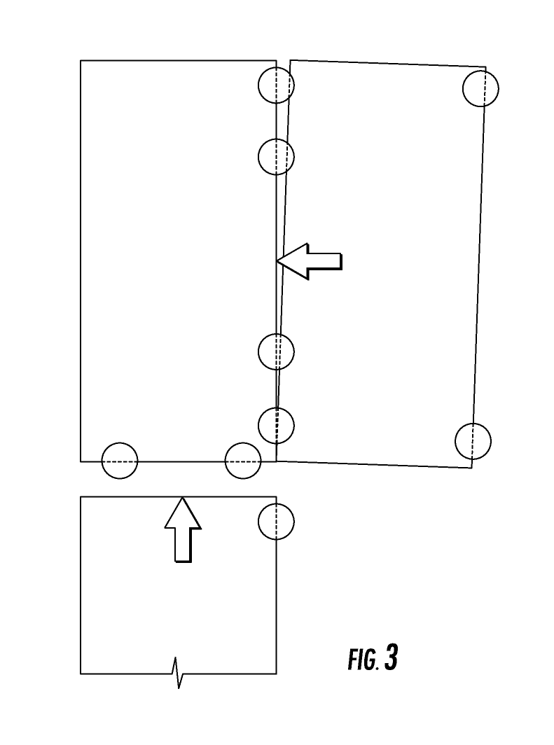

FIG. 3, which illustrates an embodiment of a module array assembly sequence that may be used with a dual insulated 3D-GFRP power block as disclosed herein, includes embodiments of electrical connections that may be employed to connect PV panels, as illustrated herein. The array formed by the PV panels can provide sufficient structural integrity such that racking systems that may be required with conventional solar panels may be reduced or eliminated. Instead, as illustrated by this embodiment, the racking is eliminated with a fastener that fastens the structural framework of the system to the roof as well as to the adjacent panels. The fastener employed in this embodiment is a “standoff-shoe” but other fasteners may be used. This figure also illustrates the use of an electrical connector pin, which may be used to connect one or more than one or all of the panels a PV array at the time of their installation. This may be achieved as a part of the installation of the standoff-riser into the power rail. Another fastener, e.g., a nylon bolt fastener, may be used to close the gap between panels.

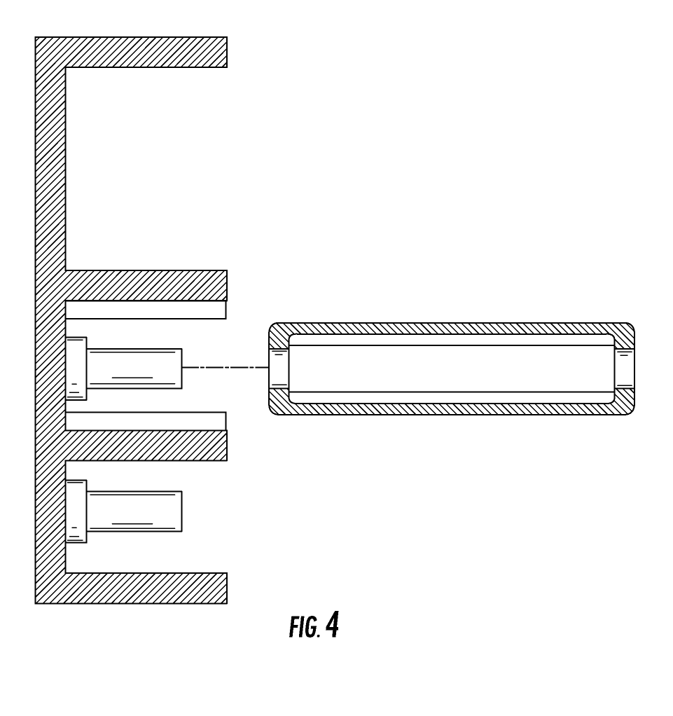

FIG. 4 illustrates an embodiment of a plug-in electrical connector and its interface that may be used with the dual-insulated 3D-GFRP power rail as disclosed herein. FIG. 4 illustrates an embodiment of a framing rail and associated electrical connector pin, which may be used to connect two adjacent panels together.

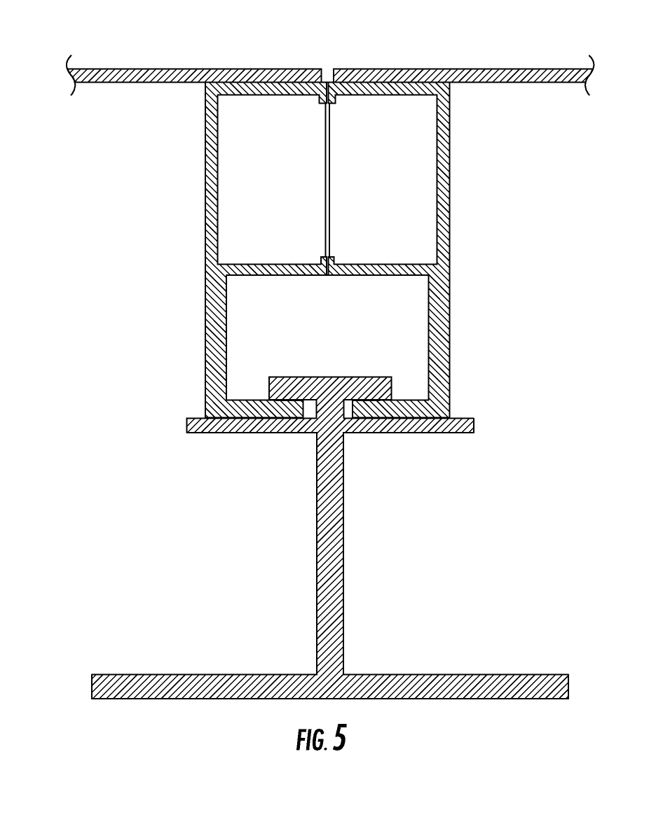

FIG. 5 illustrates an embodiment of a plug-in electrical connector and its interface that may be used with the dual-insulated 3D-GFRP power rail as disclosed herein. FIG. 5 shows the interconnected power blocks which are ready to be placed into service. In this embodiment, a plastic fastener (nylon) is used to draw two rails into structural proximity in a manner that affixes them with the standoff shoe. This embodiment also illustrates the optional use of the pin type, electrical connector (see FIG. 4) to interconnect the bus bars from these AC Power Rails.

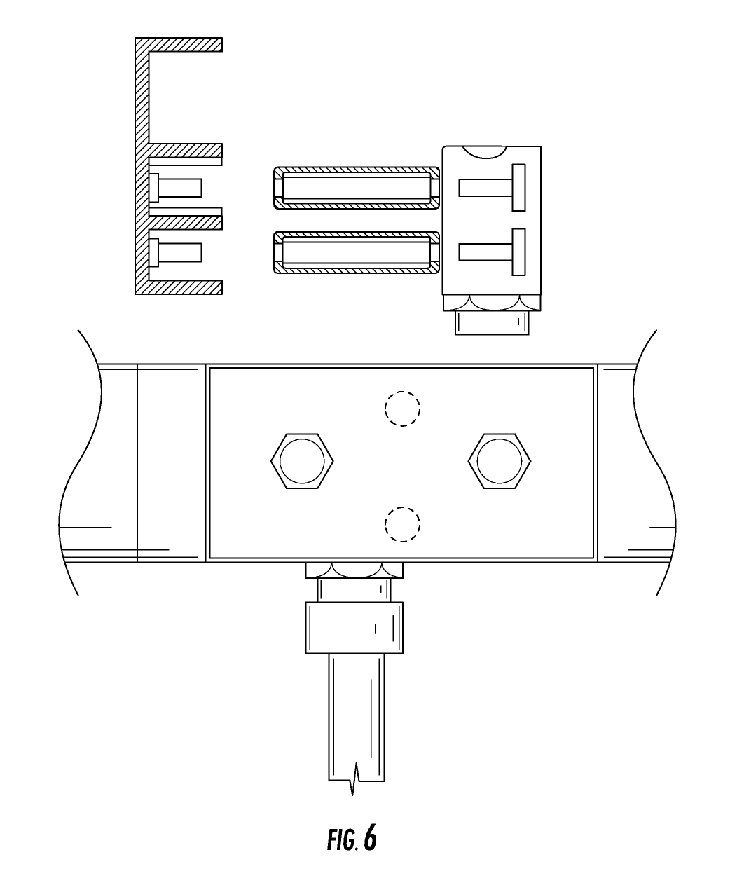

FIG. 6 illustrates an embodiment for attaching a dual insulated 3D-GFRP PV panel in accordance with this disclosure to a grid interfacing junction/transition box. This figure illustrates one embodiment for carrying power from the panel and an optional array of a multiplicity of these panels, which form an array of same. This feature provides the mechanism for delivering (maintaining) the dual insulation system feature from the power block panel to the junction box. In this embodiment, the pin is sized to functionally engage with a receptor. The bus bar is fitted with a cylindrical receptor element. As illustrated, there a dual insulated connector plug is provided (here shown as constructed of 2 inch pultrusion channel housing. A potting liquid port for potting liquid is shown, as is a pultrusion rail, Bolts (e.g., nylon) are shown as is a cable that leads to a junction box.

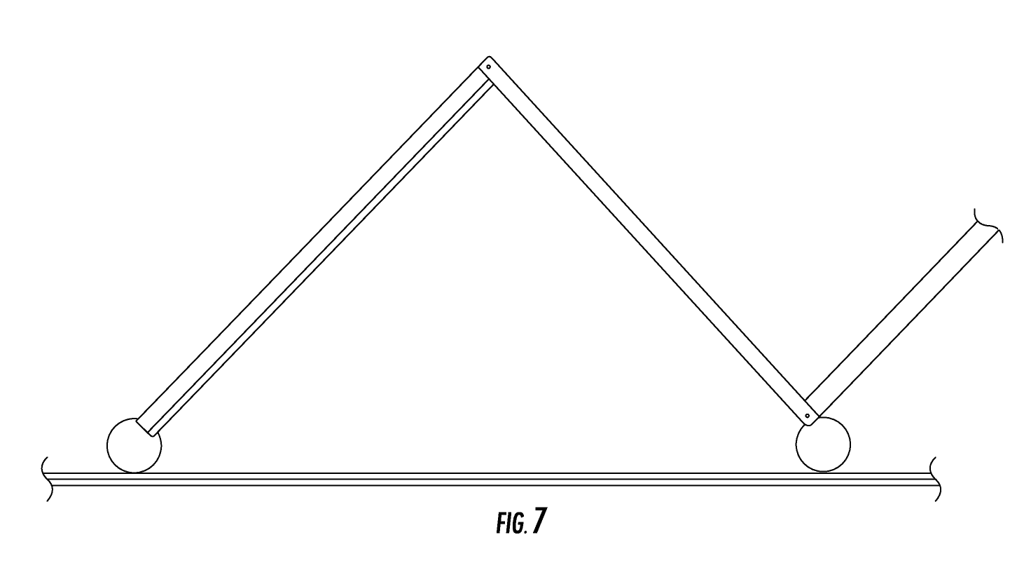

FIG. 7 illustrates an embodiment for attaching a dual insulated 3D-GFRP AC-PV in accordance with this disclosure to a flat roof. In this embodiment, the installation permits a solar array to be mounted on a flat roof structure. This interconnect is also designed to satisfy the “dual insulation” performance feature while providing the connection to move power to the junction box.

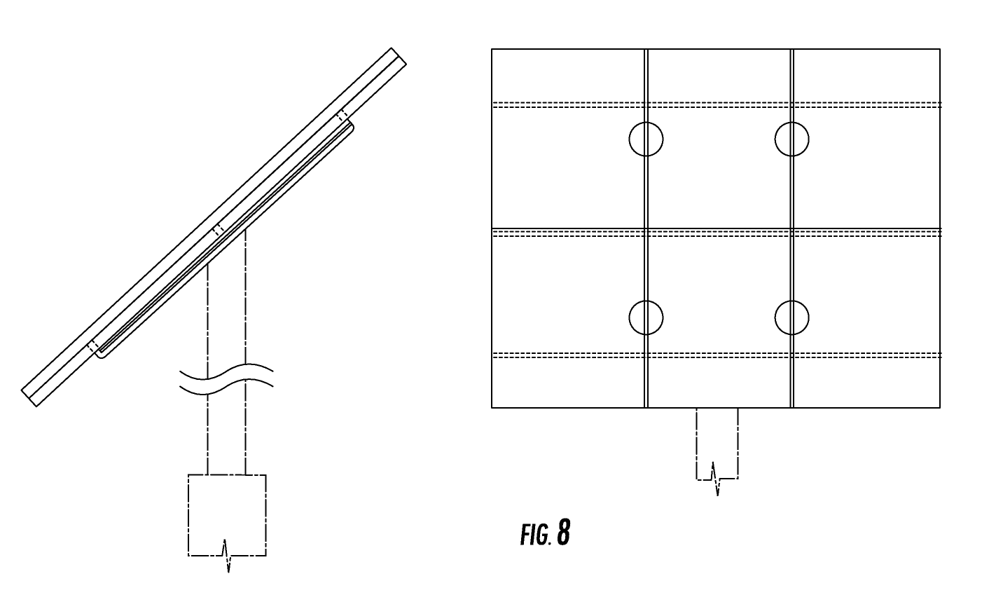

FIG. 8 illustrates an embodiment for incorporating a dual insulated 3D-GFRP AC-PV in accordance with this disclosure to a ground mounted array of six panels. In this embodiment, the entire array is connected electrically and structurally by installing a standoff-shoe and the electrical interconnect pins at the locations shown in the figure. There are no external wires between the modules or the ancillary electrical system. In this embodiment, the entire electrical system is dual insulated and thus the need for a grounding circuit is eliminated. The physical installation of the panels results in their simultaneous electrical interconnection, and the design of this embodiment of an electrical system is such that it assures proper connection of the electrical output.

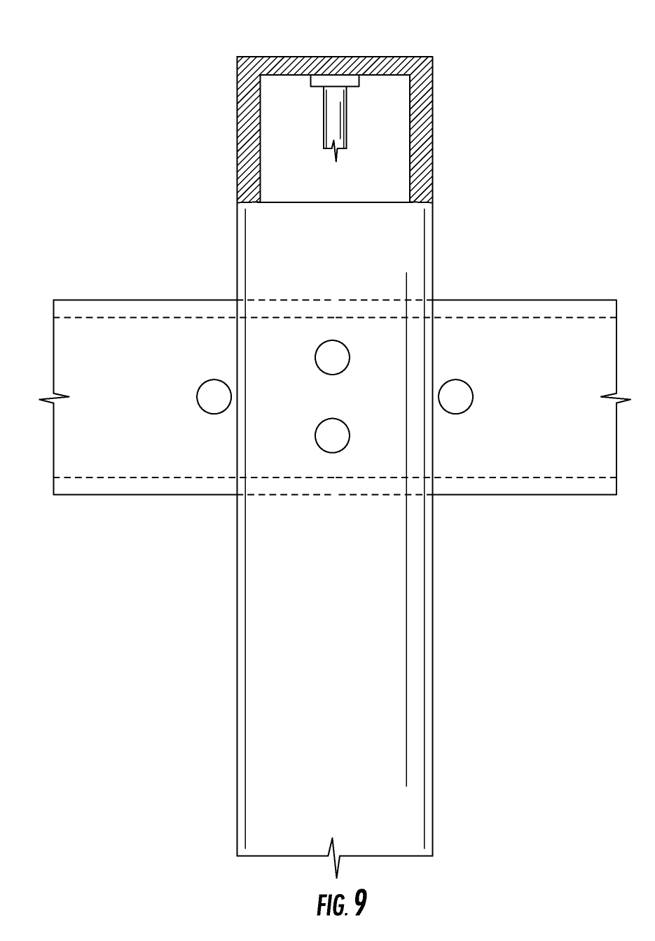

FIG. 9 illustrates an embodiment of an electrical interconnect system that may be used with a vertical power rail interconnection system in accordance with this disclosure for attaching a dual insulated 3D-GFRP AC-PV in accordance with this disclosure to a flat roof installation. This figure provides additional detail of the configuration and illustrates the interaction of the power rail interconnection system with both the junction box as well as the panel.

Embodiments of the panels provided herein this can provide one or more of the following benefits:

Panels are a fully integrated package in which the electronics, including the micro-converter to convert DC to AC, are included in the panels themselves;

Simplified installation by virtue of the included electronics; Simplified installation by virtue of the dual insulation, thereby eliminating the need for a grounding circuit;

Simplified installation by virtue of the absence of external wires associated with the PV panel;

Increased safety due to the presence of a dual insulation system arrangement;

Decreased threat of lightning strikes for embodiments that eliminate exposed metal conductor features and their corresponding grounding networks;

Incorporation of non-metallic railings as the electrical and electronic enclosure elements;

Incorporation of a heat-dissipation feature into the integrated PV panel, which may contribute to a lowering of PV cell's operating temperature, thereby potentially also resulting in an improvement in energy conversion efficiency;

Reduced costs due to reduced installation times and increased simplicity, which can be due at least in part to the dual insulated feature, which eliminates the need for external wiring and a grounding circuit;

Reduced hazards to installation personnel;

Reduced weight of the installed solar PV system;

Potentially improved operational reliability;

1. A sealed panel for collecting solar photovoltaic power comprising: a solar module which is integrally mounted in proximate connection with an electrically insulating enclosure;

2. A panel according to claim 1 wherein the said apparatus outputs only AC power.

3. A panel according to claim 2, wherein the panel is able to provide AC power without external electrical wiring.

4. A panel according to claim 3, wherein the panel comprises an AC bus bar.

5. A panel according to claim 4, wherein the sealed panel and associated electronic components and circuitry are provided within a dual insulated enclosure.

6. A panel according to claim 5, comprising a DC to AC micro-inverter.

7. A panel according to claim 6, wherein the micro-inverter's AC output is connected to an AC distribution network.

8. An array comprising a multiplicity of interconnected panels according to claim 1.

9. An array according to claim 8, wherein there are no exposed external wires between the panels.

10. An array according to claim 9, wherein there are no exposed external wires between the panels and a terminal junction box that receives AC power from the array.

11. An array according to claim 10, comprising parallel interconnections between adjacent panels via an electrically conductive bus enabled network.

12. An array according to claim 11, wherein the panels and their associated electronic components and circuits are connected by an electrical connector that maintains the integrity of the dual insulated design.

13. An array according to claim 12, wherein the AC output is connected to the AC distribution network in a manner that permits weather-tight electrical interconnection to a multiplicity of interconnected panels.

14. An array according to claim 13, wherein electrical interconnection is achieved by a sliding electrical pin:socket connector.

15. An array of panels according to claim 14, wherein this pin:socket connector precludes accidental contact during installation of the system.

16. An array according to claim 15, wherein the pin:socket connector is weather-tight and maintains the dual installation feature of the panels and array.

17. An array according to claim 16, wherein the panel and weather-tight interconnecting pin:socket element meets UL standards for a dual insulated electrical appliance.

18. A method of reducing lightening strikes to a PV array by providing an array of dual-insulated PV panels according to claim 17.

19. (canceled)

20. An array according to claim 14, that does not require an grounding circuit.

21. (canceled)

22. An installation of an array of PV panels that does not include an auxiliary grounding circuit.

23. (canceled)
